(19) United States
(12) Patent Application Publication
(10) Pub. No.: US 2026/0353931 A1
(43) Pub. Date: Nov. 5, 2026

(54) DISPLAY PANEL, MANUFACTURING METHOD THEREOF, AND DISPLAY DEVICE

(71) Applicant: WUHAN TIANMA MICROELECTRONICS CO., LTD. SHANGHAI BRANCH, Shanghai (CN)

(72) Inventor: Shuangying CAO, Shanghai (CN)

(73) Assignee: WUHAN TIANMA MICROELECTRONICS CO., LTD. SHANGHAI BRANCH, Shanghai (CN)

(21) Appl. No.: 19/724,990

(22) Filed: Jun. 30, 2026

(30) Foreign Application Priority Data
Dec. 30, 2025 (CN) 202512038836.1

(51) Int. Cl. H10K 59/122; H10K 50/19; H10K 59/12; H10K 59/80; H10K 102/00

(52) U.S. Cl. CPC H10K 59/122; H10K 50/19; H10K 59/1201; H10K 59/871; H10K 59/8792; H10K 2102/351

(57) ABSTRACT

A display panel, a manufacturing method thereof, and a display device are provided. The display panel includes: a first substrate; an anode layer, including a plurality of anode units; a pixel definition layer, having a plurality of first openings and a plurality of grooves, and the first openings correspond to the anode units, penetrate the pixel definition layer, and expose at least a portion of a surface of the respective anode units, and a projection of each groove on the first substrate is within a gap between projections of adjacent anode units on the first substrate; a first inclination angle is formed between a sidewall and a bottom of the first opening, a second inclination angle is formed between a sidewall and a bottom of the groove, and the first inclination angle is greater than the second inclination angle.

### CROSS REFERENCE OF RELATED APPLICATION

The present application claims the priority to Chinese Patent Application No. 202512038836.1, titled “DISPLAY PANEL, MANUFACTURING METHOD THEREOF, AND DISPLAY DEVICE”, filed on Dec. 30, 2025 with the China National Intellectual Property Administration (CNIPA), which is incorporated herein by reference in its entirety.

### FIELD

The present disclosure relates to the field of display technology, and in particular to a display panel, a manufacturing method thereof, and a display device.

### BACKGROUND

Organic light-emitting diode (OLED) display technology has become one of the mainstream display solutions due to its self-luminescence, wide viewing angle, high contrast and flexibility. However, a display panel adopting the OLED technology currently suffers from a color shift phenomenon when displaying at a low grayscale.

### SUMMARY

In view of the above problems, the present disclosure provides a display panel and a manufacturing method thereof, and a display device including the display panel, to alleviate the color shift phenomenon under low grayscale display.

A display panel includes:
a first substrate;
an anode layer disposed on a first side of the first substrate, the anode layer including a plurality of anode units;
a pixel definition layer disposed on a side of the anode layer away from the first substrate, the pixel definition layer having a plurality of first openings and a plurality of grooves, and the first openings correspond to the respective anode units, penetrate the pixel definition layer, and expose at least a portion of a surface of the respective anode units, and a projection of each groove on the first substrate is within a gap between projections of adjacent anode units on the first substrate;
for each of the plurality of first openings and each of the plurality of grooves, a first inclination angle is formed between a sidewall of the first opening and a bottom of the first opening, a second inclination angle is formed between a sidewall of the groove and a bottom of the groove, and the first inclination angle is greater than the second inclination angle.

A display device includes the above display panel.

A manufacturing method of a display panel, includes:
forming a first substrate;
forming an anode layer on a first side of the first substrate, the anode layer including a plurality of anode units;
forming a pixel definition layer on a side of the anode layer away from the first substrate, the pixel definition layer having a plurality of first openings and a plurality of grooves, and the first openings correspond to the respective anode units, penetrate the pixel definition layer, and expose at least a portion of a surface of the respective anode units, and a projection of each groove on the first substrate is within a gap between projections of adjacent anode units on the first substrate;
for each of the plurality of first openings and each of the plurality of grooves, a first inclination angle is formed between a sidewall of the first opening and a bottom of the first opening, a second inclination angle is formed between a sidewall of the groove and a bottom of the groove, and the first inclination angle is greater than the second inclination angle.

### BRIEF DESCRIPTION OF THE DRAWINGS

The above and other features, advantages and aspects of various embodiments of the present disclosure will become more apparent with reference to the accompanying drawings and the following detailed description. Throughout the drawings, the same or similar reference numerals denote the same or similar elements. The drawings are schematic, and originals and elements are not necessarily drawn to scale.

FIG. 1 is a schematic structural diagram of a display panel in the prior art;

FIG. 2 is another schematic structural diagram of a display panel in the prior art;

FIG. 3 is a schematic structural diagram of a display panel provided by the present disclosure;

FIG. 4 is a schematic structural diagram of another display panel provided by the present disclosure;

FIG. 5 is a schematic structural diagram of yet another display panel provided by the present disclosure;

FIG. 6 is a schematic structural diagram of still another display panel provided by the present disclosure;

FIG. 7 is a schematic structural diagram of yet another display panel provided by the present disclosure;

FIG. 8 is a top view of still another display panel provided by the present disclosure;

FIG. 9 is a schematic structural diagram of yet another display panel provided by the present disclosure;

FIG. 10 is a schematic structural diagram of still another display panel provided by the present disclosure;

FIG. 11 is a partial top view of yet another display panel provided by the present disclosure;

FIG. 12 is a partial top view of still another display panel provided by the present disclosure;

FIG. 13 is a schematic structural diagram of still another display panel provided by the present disclosure;

FIG. 14 is a schematic diagram of yet another display device provided by the present disclosure;

FIG. 15 is a flow chart of a manufacturing method of a display panel provided by the present disclosure; and

FIG. 16 to FIG. 29 are partial structural diagrams involved in a manufacturing process of a display panel provided by the present disclosure.

### DETAILED DESCRIPTION OF THE EMBODIMENTS

The embodiments of the present disclosure will be described below with reference to the accompanying drawings in the embodiments of the present disclosure. The terms used in the detailed description of the present disclosure are used to explain specific embodiments of the present disclosure and are not intended to limit the present disclosure.

The embodiments of the present disclosure will be described below with reference to the accompanying drawings. It can be understood that, with the development of technology and the emergence of new scenarios, the embodiments provided by the present disclosure are also applicable to similar problems.

The terms “first”, “second”, etc. in the description and claims of the present disclosure and the above drawings are used to distinguish similar objects and are not necessarily used to describe a specific order or sequence. The terms used can be interchanged under appropriate circumstances, which is a distinguishing method used when describing objects of the same attribute in the embodiments of the present disclosure. In addition, the terms “include” and “have” and any variations thereof are intended to cover non-exclusive inclusion, and a process, method, system, product or device including a series of units is not necessarily limited to those units, but may include other units not explicitly listed or inherent to these processes, methods, products or devices.

As described in the background section, currently, a display panel adopting the OLED technology suffers from a color shift phenomenon when displaying at a low grayscale.

Currently, display panels adopting the OLED technology include those having a single light-emitting layer and those having at least two light-emitting layers, i.e., display panels adopting a tandem OLED technology.

A conventional OLED is a current-driven device, and its luminous brightness is directly related to the driving current. If the current is increased to pursue higher brightness, the aging of the organic material in the OLED will be accelerated, resulting in a significantly shortened device lifetime, which becomes a key contradiction restricting the further improvement of OLED performance. To solve this contradiction, the tandem OLED technology emerges. Its core principle is: under the same current, multiple OLEDs work in series to superpose light efficiency; conversely, to achieve the same brightness, the current required for each OLED is significantly reduced, thereby greatly slowing down the material aging in the OLEDs and prolonging the device lifetime. Therefore, compared with display panels having a single light-emitting layer, display panels adopting the tandem OLED technology are more advantageous.

Taking a display panel adopting the tandem OLED technology as an example, the reason for the color shift phenomenon of the display panel is analyzed below.

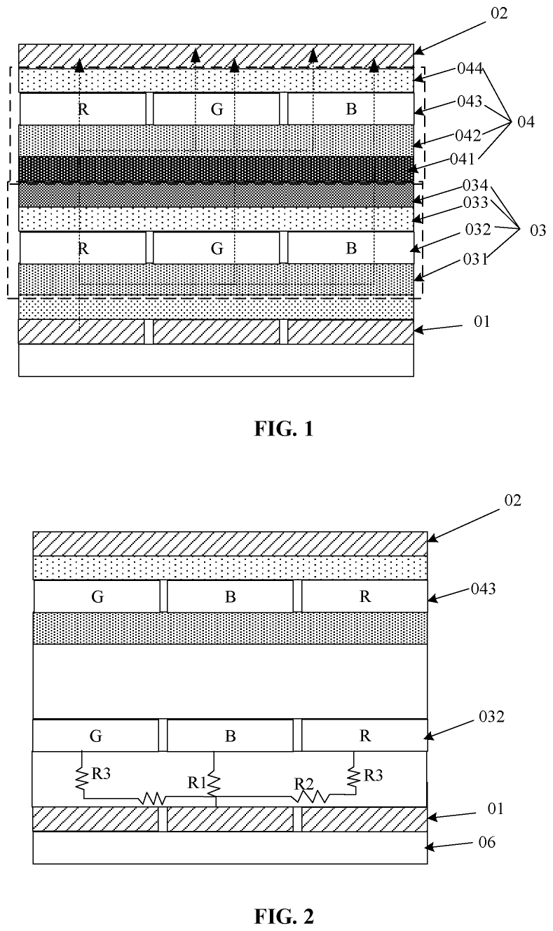

As shown in FIG. 1, FIG. 1 illustrates a schematic structural diagram of a display panel adopting the tandem OLED technology. It can be seen from FIG. 1 that the display panel includes an anode layer 01 and a cathode layer 02, and a first light-emitting structure 03 and a second light-emitting structure 04 stacked between the anode layer 01 and the cathode layer 02, where the first light-emitting structure 03 includes a hole transport layer 031, a light-emitting unit layer 032, an electron transport layer 033 and an N-type charge generation layer 034 stacked in a direction away from the anode layer 01, and the second light-emitting structure 04 includes a P-type charge generation layer 041, a hole transport layer 042, a light-emitting unit layer 043 and an electron transport layer 044 stacked in a direction away from the anode layer 01.

In the above embodiment, the light-emitting unit layer includes light-emitting units of three colors, i.e., R light-emitting units, G light-emitting units and B light-emitting units. Different light-emitting units are driven by different anodes in the anode layer, to realize independent control of different light-emitting units.

However, in the above structure, structures disposed between the anode layer and the light-emitting unit layer, such as the hole transport layer 031, are formed as continuous structures. Therefore, when a voltage signal is applied to the anode corresponding to any light-emitting unit, the charges transmitted to the hole transport layer 031 will select a transmission path according to the vertical impedance and the horizontal impedance.

As shown in FIG. 2, the vertical impedance between the B light-emitting unit in the first light-emitting structure and the substrate 06 is denoted as R1, the horizontal impedance is denoted as R2, and the vertical impedance between the R light-emitting unit or the G light-emitting unit in the first light-emitting structure and the substrate 06 is denoted as R3, and the horizontal impedance R2 includes the horizontal impedance of each layer structure between the anode layer 01 and the light-emitting unit layer 032.

If the display panel works in a medium and high grayscale brightness scene, when the anode of the B light-emitting unit outputs a driving signal and the anodes of the R light-emitting unit and the G light-emitting unit do not output signals, R1 is far smaller than R2 and R3. At this time, the driving signal output by the anode of the B light-emitting unit only flows through the B light-emitting unit, and the R light-emitting unit and the G light-emitting unit are not lit.

If the display panel works in a low grayscale brightness scene, when the anode of the B light-emitting unit outputs a driving signal and the anodes of the R light-emitting unit and the G light-emitting unit do not output signals, it is likely that R3 is smaller than R1. In the case where R3 is too small and R1 is not far smaller than R2+R3, at this time, the driving signal output by the anode of the B light-emitting unit not only flows through the B light-emitting unit, but also firstly transmits laterally and then transmits vertically, flowing through the R light-emitting unit and/or the G light-emitting unit, causing the R light-emitting unit and/or the G light-emitting unit that should not be lit to be lit, resulting in unintended lighting and causing color shift in the display of the display panel.

Similarly, the charge generation layer (including the N-type charge generation layer and the P-type charge generation layer) between the first light-emitting unit layer 032 and the second light-emitting unit layer 043 is also formed as the continuous structure. In a low grayscale brightness application scene, when the B light-emitting unit emits light, the driving signal output by the anode of the B light-emitting unit may also be laterally transmitted to the region where the R light-emitting unit and/or the G light-emitting unit are disposed via the charge generation layer, causing the R light-emitting unit and/or the G light-emitting unit that should not be lit to be lit, resulting in unintended lighting and causing color shift in the display of the display panel.

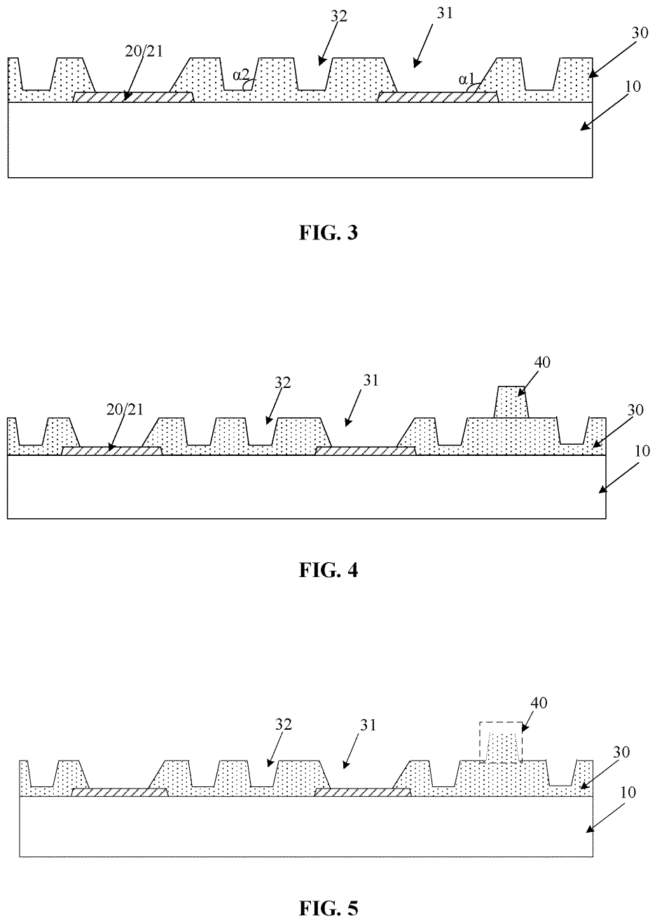

In view of this, an embodiment of the present disclosure provides a display panel. As shown in FIG. 3, the display panel includes:
a first substrate 10;
an anode layer 20 disposed on a first side of the first substrate 10, the anode layer 20 including a plurality of anode units 21;
a pixel definition layer 30 disposed on a side of the anode layer 20 away from the first substrate 10, the pixel definition layer 30 having a plurality of first openings 31 and a plurality of grooves 32; and the first openings 31 correspond to the respective anode units 21, penetrate the pixel definition layer 30, and expose at least a portion of a surface of the respective anode units 21; and a projection of each groove 32 on the first substrate 10 is within a gap between projections of adjacent anode units 21 on the first substrate 10.

In the display panel provided by the embodiment of the present disclosure, the pixel definition layer 30 not only has the first openings 31 for at least partially exposing the surface of the anode units 21, and subsequently formed light-emitting units are electrically connected to the anode units 21 through the first openings 31, but also has the grooves 32, the projections of the grooves 32 on the first substrate 10 being within the gaps between projections of adjacent anode units 21 on the first substrate 10. Thus, by providing the grooves 32 between adjacent anode units 21 in a plane parallel to the first substrate 10, the lateral resistance of each continuous layer structure formed in the pixel definition layer 30 away from the first substrate 10 is increased, transmission of lateral current is reduced, the probability of unintended lighting occurring during display of the display panel is reduced, and the color shift phenomenon of the display panel is alleviated.

In this embodiment, the groove 32 does not penetrate the pixel definition layer 30, but only extends into a partial depth inside the pixel definition layer 30, to increase the contact area between the first substrate 10 and the pixel definition layer 30 and improve the adhesion between the first substrate 10 and the pixel definition layer 30. It should also be noted that if the groove 32 at least partially overlaps with the anode unit 21 in a direction perpendicular to the first substrate 10, the groove 32 does not penetrate the pixel definition layer 30 but only extends into a partial depth inside the pixel definition layer 30, which can also prevent the anode unit 21 from being exposed by the pixel definition layer 30 at the position of the groove 32.

In addition, in this embodiment, a first inclination angle α1 is formed between a sidewall of the first opening 31 and a bottom of the first opening 31, a second inclination angle α2 is formed between a sidewall of the groove 32 and a bottom of the groove 32, and the first inclination angle α1 is greater than the second inclination angle α2, and the first opening 31 has a larger inclination angle and a relatively gentle sidewall slope, thereby ensuring continuity of each layer at the first opening 31 when subsequently forming the layers in the first opening 31; meanwhile, by using a smaller inclination angle, the sidewall slope of the groove 32 is steeper, enabling poor continuity of the subsequently formed layers at the groove 32, or enabling thinner thickness at the corner of the groove 32, further increasing the lateral resistance of each layer at the groove 32, reducing transmission of lateral current, lowering the probability of unintended lighting occurring during display of the display panel, and alleviating the color shift phenomenon of the display panel.

In one embodiment of the present disclosure, the value range of the first inclination angle α1 is 140° to 160°, to reduce the area occupied by the slope of the first opening 31 while ensuring the continuity of the layers subsequently formed on the surface of the first opening 31, which facilitates the setting of more display pixels under the premise of the same display area and improves the resolution of the display panel. However, the present disclosure is not limited in this aspect, and may vary depending on the specific circumstances.

In one embodiment of the present disclosure, the value range of the second inclination angle α2 is 90° to 120°, to ensure that the provision of the groove 32 can reduce the probability of unintended lighting occurring during display of the display panel and alleviate the color shift phenomenon of the display panel. However, the present disclosure is not limited in this aspect, and may vary depending on the specific circumstances.

Based on any of the above embodiments, in an embodiment of the present disclosure, as shown in FIG. 4, the display panel further includes: a support 40 disposed on a side of the pixel definition layer 30 away from the first substrate 10, for supporting a mask when other layers are subsequently formed after the light-emitting layers are formed, preventing the mask from touching the light-emitting layers and damaging the light-emitting layers, affecting the display of the display panel, and also preventing the mask from being worn.

Based on the above embodiment, in an embodiment of the present disclosure, as shown in FIG. 5, the support 40 and the pixel definition layer 30 are formed as an integral structure, and the support 40 and the pixel definition layer 30 can be formed using the same layer, simplifying the process of the display panel and reducing the cost of the display panel.

Based on any of the above embodiments, in an embodiment of the present disclosure, the pixel definition layer 30 is a positive photoresist layer, and the groove 32 and the first opening 31 can be formed in the same process step, further simplifying the process flow of the display panel and reducing the cost of the display panel. In this embodiment, if the display panel further includes the support 40, the groove 32, the first opening 31 and the support 40 are formed in the same process step, to further simplify the process flow of the display panel and reduce the cost of the display panel.

The development of a negative photoresist layer is “switch” type. In its development process: above a critical exposure dose, the photoresist layer becomes completely insoluble, and below this dose, it remains completely soluble (or nearly completely soluble). Although there is a transition zone near the critical dose, this transition zone is usually very narrow and difficult to accurately control, and the groove 32 and the first opening 31 cannot be formed in the same process step. Therefore, if a negative photoresist layer is used to form the pixel definition layer 30 in the display panel provided by the embodiment of the present disclosure, additional processes such as photolithography, dry etching, and stripping are needed, complicating the process of the display panel.

Moreover, compared with the negative photoresist layer, the positive photoresist layer has better toughness. In the display panel provided by the embodiment of the present disclosure, forming the pixel definition layer 30 by using the positive photoresist layer facilitates the bending performance of the display panel, thereby facilitating its application in foldable screen scenarios.

In one embodiment of the present disclosure, the pixel definition layer 30 is made of polyimide-based material. However, the present disclosure is not limited in this aspect, and may vary depending on the specific circumstances.

In one embodiment of the present disclosure, the formation process of the grooves 32 and the first openings 31 includes exposure, development and curing, and includes: forming the pixel definition layer 30 on the side of the anode layer 20 away from the first substrate 10, exposing the pixel definition layer 30, where a first region of the pixel definition layer 30 is exposed with light of a first dose, a second region of the pixel definition layer 30 is exposed with light of a second dose, and then developing and curing the pixel definition layer 30, to obtain the pixel definition layer 30 having the first openings 31 and the grooves 32, where the first region is for forming the grooves 32, the second region is for forming the first openings 31, and the first dose is smaller than the second dose.

In one embodiment of the present disclosure, the curing process includes: initial curing and deep curing. The initial curing is performed at 150 °C-180 °C, where low-temperature loading enables thermal cross-linking of the materials in the display panel, increases Tg (glass transition temperature), and alleviates reflow during the subsequent high-temperature process; the deep curing is performed at 230 °C-270 °C, to completely cure the pixel definition layer 30, preventing it from absorbing moisture or releasing small organic molecules in subsequent processes.

Based on any of the above embodiments, in an embodiment of the present disclosure, the pixel definition layer 30 is a light-absorbing layer, to use the pixel definition layer 30 to absorb light incident from the display surface into the display panel, reducing reflection and thereby improving the display quality of the display panel. In one embodiment of the present disclosure, the pixel definition layer 30 is a black material layer, and the pixel definition layer 30 has a better light-absorbing effect. The present disclosure is not limited in this aspect, and may vary depending on the specific circumstances.

Moreover, in the display panel provided by the embodiment of the present disclosure, by configuring the pixel definition layer 30 as a light-absorbing layer, the reflection from the display surface of the display panel is reduced and the display quality is improved. As a result, the need for a polarizer is eliminated, which is beneficial to improving the bending performance of the display panel.

Based on any of the above embodiments, in an embodiment of the present disclosure, the display panel adopts the tandem OLED technology, that is, the display panel includes at least two light-emitting layers, to improve the display brightness of the display panel under the same driving current, or reduce the driving current of the display panel under the same display brightness, slow down the material aging in the OLEDs, and prolong the service life. In this embodiment, as shown in FIG. 6, the display panel further includes: at least two light-emitting layers 50 disposed on a side of the anode layer 20 away from the first substrate 10, where the at least two light-emitting layers 50 include periodically arranged light-emitting units 501 of a first color, light-emitting units 502 of a second color, and light-emitting units 503 of a third color; a charge generation layer 60 disposed between adjacent light-emitting layers 50; and a cathode layer 70 disposed on a side of the at least two light-emitting layers 50 away from the first substrate 10. In one embodiment of the present disclosure, the first-color light-emitting units 501 are red light-emitting units, the second-color light-emitting units 502 are green light-emitting units, and the third-color light-emitting units 503 are blue light-emitting units. The present disclosure is not limited in this aspect, and may vary depending on the specific circumstances.

In this embodiment, a voltage difference is generated between the cathode layer 70 and the respective anode units 21 corresponding to light-emitting units, controlling the light-emitting state of the light-emitting units 500; the charge generation layer 60 is used to generate electrons and holes to drive each light-emitting unit 500.

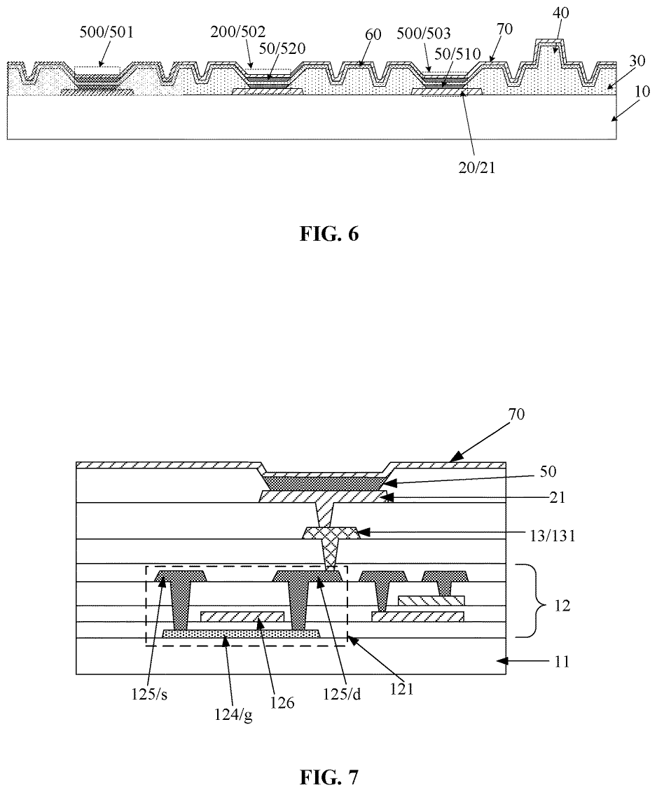

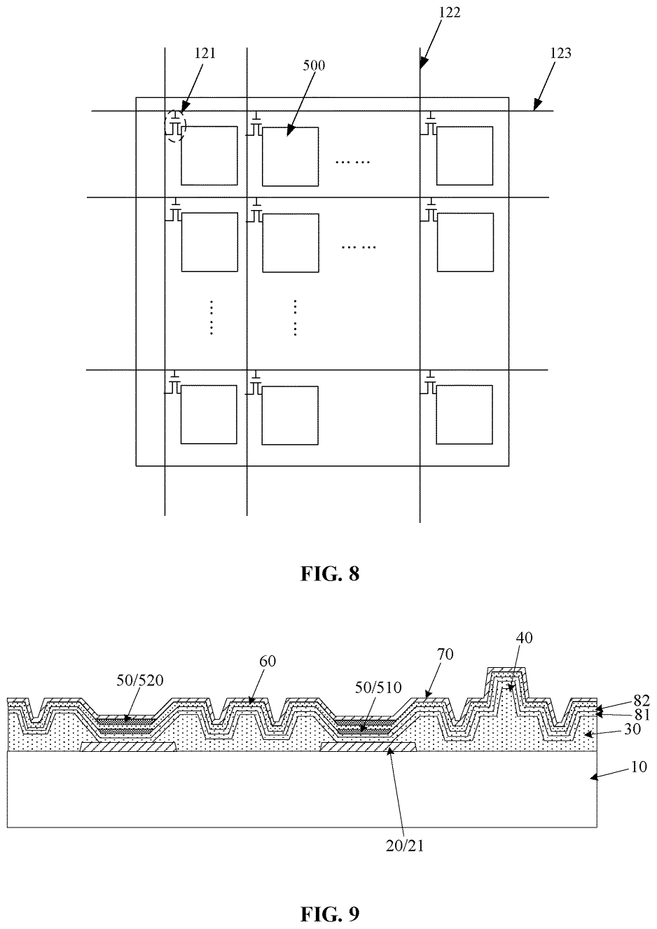

In one embodiment of the present disclosure, as shown in FIG. 7 and FIG. 8, the first substrate 10 includes a base substrate 11, and a control circuit layer 12 disposed on the surface of the base substrate 11. The control circuit layer 12 includes a plurality of thin-film transistors 121, a plurality of data lines 122 and a plurality of scan lines 123. The thin-film transistor 121 includes a gate g, a source s and a drain d, where the source s of the thin-film transistor 121 is electrically connected to the data line 122, the drain d is electrically connected to the anode unit 21, and the gate g is electrically connected to the scan line 123, to control the electrical connection between the data line 122 and the anode unit 21 under the control of a control signal output by the scan line 123, thereby controlling the voltage signal on the anode unit 21, then forming a voltage difference between the anode unit 21 and the cathode layer 70, and controlling the light-emitting state of the light-emitting unit 500 disposed between the anode unit 21 and the cathode layer 70.

In one embodiment of the present disclosure, the drain d of the thin-film transistor 121 is electrically connected to the anode unit 21 through an electrical connection structure 131. The present disclosure is not limited in this aspect, and may vary depending on the specific circumstances.

Based on the above embodiment, in an embodiment of the present disclosure, continuing to refer to FIG. 7, the display panel includes a first metal layer 124, a second metal layer 125 and a third metal layer 13 arranged in a direction away from the base substrate 11. The first metal layer 124 includes the gates g of the thin-film transistors 121 and the scan lines 123, the second metal layer 125 includes the sources s of the thin-film transistors 121, the drains d of the thin-film transistors 121 and the data lines 122, and the third metal layer 13 includes the electrical connection structures 131. A channel layer 126 is provided between the first metal layer 124 and the second metal layer 125. In this embodiment, the first metal layer 124, the second metal layer 125 and the third metal layer 13 may include additional signal lines. The present disclosure is not limited in this aspect, and may vary depending on the specific circumstances.

In one embodiment of the present disclosure, a first insulating layer is further provided between the first metal layer 124 and the channel layer 126, a second insulating layer is further provided between the channel layer 126 and the second metal layer 125, and a third insulating layer is further provided between the second metal layer 125 and the third metal layer 13. In this embodiment, any one of the first insulating layer, the second insulating layer and the third insulating layer may include only one insulating layer, or may include at least one insulating layer. The present disclosure is not limited in this aspect, and may vary depending on the specific circumstances.

Based on the above embodiment, in an embodiment of the present disclosure, as shown in FIG. 9, the display panel further includes: a hole injection layer 81 and a first hole transport layer 82 which are disposed between the anode layer 20 and the at least two light-emitting layers 50. The first hole transport layer 82 is disposed on a side of the hole injection layer 81 away from the anode layer 20. In one embodiment, the hole injection layer 81 is used to promote the injection of holes from the anode units 21 into the first hole transport layer 82, and the first hole transport layer 82 is used to transport holes to the light-emitting layers 50 and block electrons from being transported to the light-emitting layers 50.

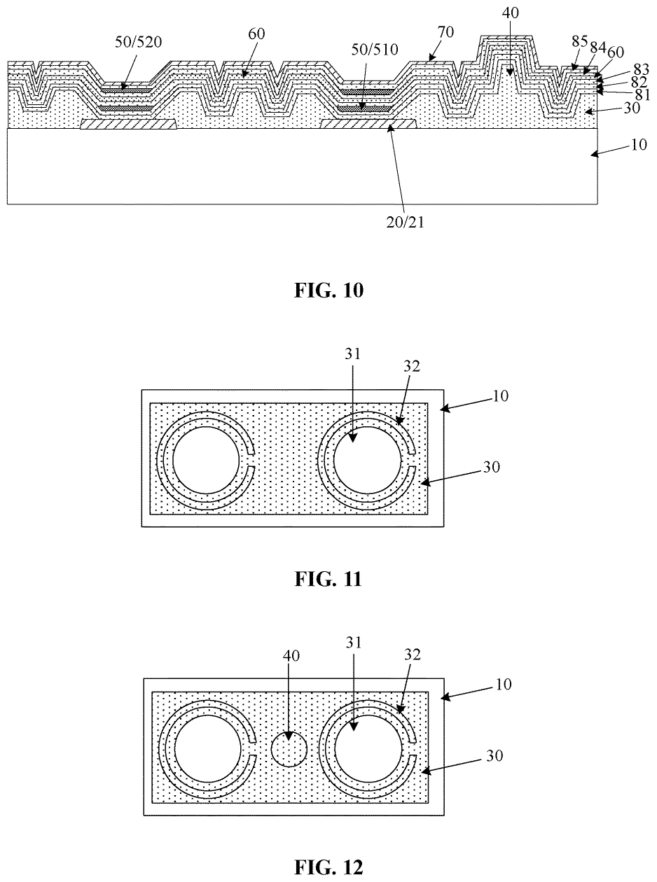

Based on the above embodiment, in an embodiment of the present disclosure, continuing to refer to FIG. 6 and FIG. 9, the at least two light-emitting layers 50 include a first light-emitting layer 510 and a second light-emitting layer 520 stacked in a direction away from the first substrate 10. In this embodiment, as shown in FIG. 10, the display panel further includes: a first electron transport layer 83 disposed between the first light-emitting layer 510 and the charge generation layer 60, a second hole transport layer 84 disposed between the charge generation layer 60 and the second light-emitting layer 520, and a second electron transport layer 85 disposed between the second light-emitting layer 520 and the cathode layer 70. The first electron transport layer 83 and the second electron transport layer 85 are used to transport electrons to the light-emitting layers and block the transport of holes, and the second hole transport layer 84 is used to transport holes and block the transport of electrons.

In one embodiment of the present disclosure, as shown in FIG. 11 and FIG. 12, FIG. 11 is a partial top view of a display panel in a region not including the support 40, and FIG. 12 is a partial top view of the display panel in a region including the support 40. The groove 32 surrounds the first opening 31, and the projection of the groove 32 on the first substrate 10 is a non-closed loop, and portions of the cathode layer 70 corresponding to the respective light-emitting units in the display panel can form an integral structure, thereby simplifying the manufacturing process of the display panel. However, the present disclosure is not limited in this aspect. In other embodiments of the present disclosure, the projection of the groove 32 on the first substrate 10 may, in one embodiment, be a closed loop. In this embodiment, portions of the cathode layer corresponding to the respective light-emitting units may be independent of each other, depending on the specific situation.

In one embodiment of the present disclosure, the projection of the groove on the first substrate may be a non-closed circular ring, or a non-closed rectangular loop, or a non-closed loop of other shapes, depending on the specific situation.

Based on the above embodiment, in an embodiment of the present disclosure, continuing to refer to FIG. 6, the display panel includes light-emitting units 500 of at least two colors, such as light-emitting units 501 of the first color, light-emitting units 502 of the second color, and light-emitting units 503 of the third color. The cathode layer 70 corresponding to light-emitting units 500 of different colors is an integral structure, thereby simplifying the process of the display panel. However, the present disclosure is not limited in this aspect, and may vary depending on the specific circumstances.

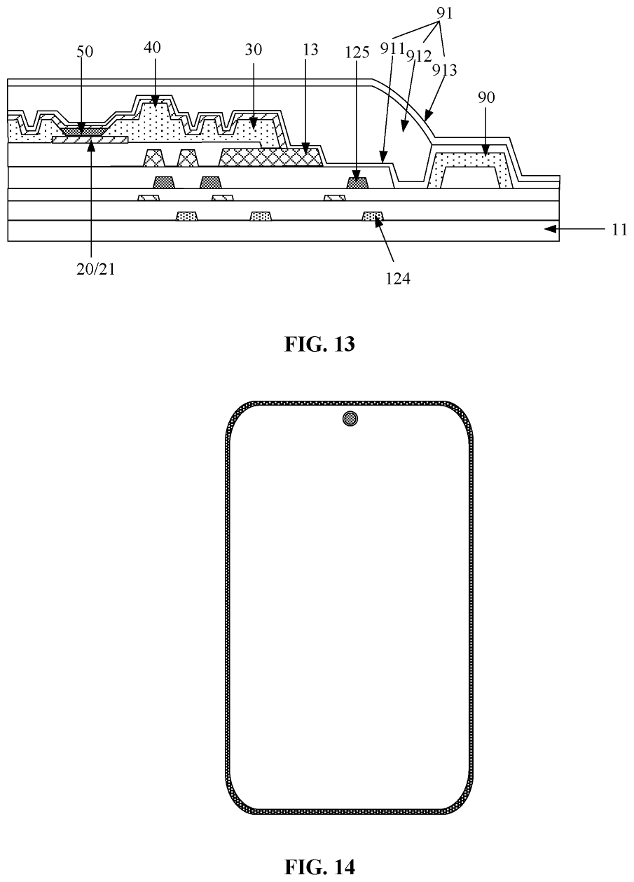

Based on any of the above embodiments, in an embodiment of the present disclosure, as shown in FIG. 13, the display panel further includes: an encapsulation layer 91 encapsulating at least the pixel definition layer 30, the light-emitting layers 50 and other structures. In one embodiment, the encapsulation layer 91 includes a stacked first inorganic layer 911, an organic layer 912 and a second inorganic layer 913, to improve the effect of the encapsulation layer 91 in isolating water and oxygen from the external environment.

Since the organic layer has a poorer effect in isolating water and oxygen than the inorganic layer, in one embodiment of the present disclosure, continuing to refer to FIG. 13, the display panel further includes: a barrier structure 90 disposed on the first side of the first substrate 10 and around a display area of the display panel. In one embodiment, when encapsulating structures such as the pixel definition layer 30 and the anode layer 20 on the first substrate 10 side, the barrier structure 90 is used to limit a boundary of the organic layer 912 in the encapsulation layer, preventing water and oxygen of the external environment from entering the interior of the display panel via the organic layer 912 in the encapsulation layer 91 and affecting the display of the display panel. In one embodiment of the present disclosure, the barrier structure 90 and the pixel definition layer 30 are formed in the same process step, to further simplify the process of the display panel and reduce the cost of the display panel.

Correspondingly, as shown in FIG. 14, an embodiment of the present disclosure further provides a display device, which may include the display panel provided by any of the above embodiments. The relevant content of the display panel has been described in the above embodiments and will not be repeated here.

In one embodiment of the present disclosure, the display device may be a mobile phone, a tablet computer, a wearable device, a vehicle-mounted device, an augmented reality (AR)/virtual reality (VR) device, a notebook computer, an ultra-mobile personal computer (UMPC), a netbook, a personal digital assistant (PDA), etc. The embodiments of the present disclosure are not limited thereto, and may vary depending on the specific circumstances.

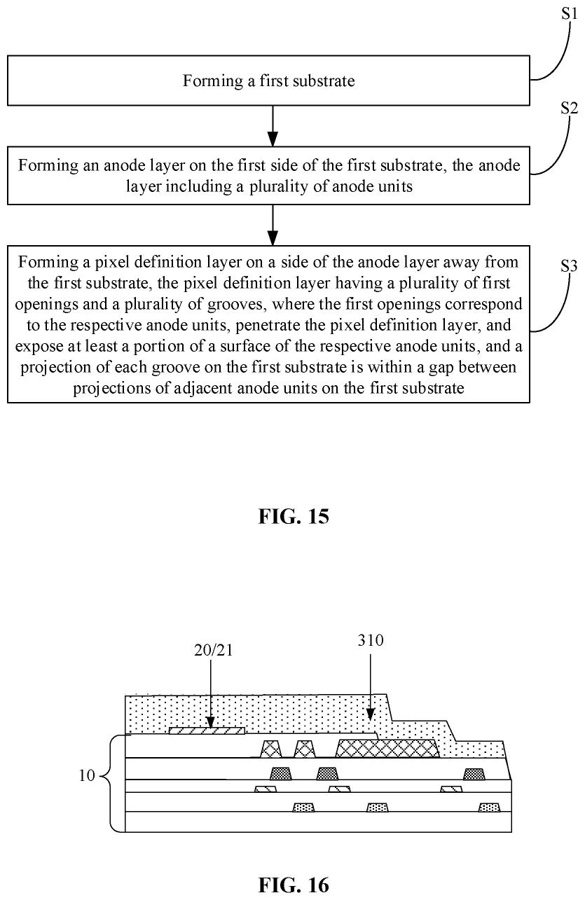

In addition, an embodiment of the present disclosure further provides a manufacturing method of a display panel. As shown in FIG. 15, the manufacturing method includes the following steps.

In S1, a first substrate is formed.

In one embodiment of the present disclosure, the first substrate includes a base substrate and a control circuit layer disposed on a surface of the base substrate, and the control circuit layer includes a plurality of thin-film transistors, a plurality of data lines and a plurality of scan lines, and each thin-film transistor includes a gate, a source and a drain, and the source of the thin-film transistor is electrically connected to the data line, the drain is electrically connected to an anode unit to be formed later, and the gate is electrically connected to the scan line, to control an electrical connection between the data line and the anode unit under the control of a control signal output by the scan line, thereby controlling a voltage signal on the anode unit.

In this embodiment, forming the first substrate includes:
forming a buffer layer on a surface of the base substrate, in one embodiment, the base substrate is a glass substrate or a polyimide (PI) substrate, but the present disclosure is not limited in this aspect, and may vary depending on the specific circumstances;
forming a first metal layer on a surface of the buffer layer away from the base substrate, the first metal layer including the gates of the thin-film transistors and the scan lines;
forming a first insulating layer on a surface of the first metal layer away from the buffer layer;
forming a channel layer on a side of the first insulating layer away from the first metal layer, the channel layer including channels of the thin-film transistors;
forming a second insulating layer on a side of the channel layer away from the first insulating layer;
forming a second metal layer on a side of the second insulating layer away from the channel layer, the second metal layer including the sources and the drains of the thin-film transistor and the data line; and
forming a third insulating layer on a side of the second metal layer away from the second insulating layer, the third insulating layer having a plurality of through holes for realizing electrical connection between the drains and the anode units, where the third insulating layer is, in one embodiment, a planarization layer, but the present disclosure is not limited in this aspect, and may vary depending on the specific circumstances.

In S2, an anode layer is formed on the first side of the first substrate, the anode layer including a plurality of anode units.

In one embodiment of the present disclosure, forming the anode layer on the first side of the first substrate includes: forming a first electrode layer on the first side of the first substrate; and etching the first electrode layer to form the plurality of anode units, completing the formation of the anode layer.

In S3, a pixel definition layer is formed on a side of the anode layer away from the first substrate, the pixel definition layer having a plurality of first openings and a plurality of grooves, where the first openings correspond to the respective anode units, penetrate the pixel definition layer, and expose at least a portion of a surface of the respective anode units, and a projection of each groove on the first substrate is within a gap between projections of adjacent anode units on the first substrate.

In one embodiment of the present disclosure, forming the pixel definition layer on the side of the anode layer away from the first substrate includes the following steps.

As shown in FIG. 16, a positive photoresist layer 310 is formed on the side of the anode layer 20 away from the first substrate 10.

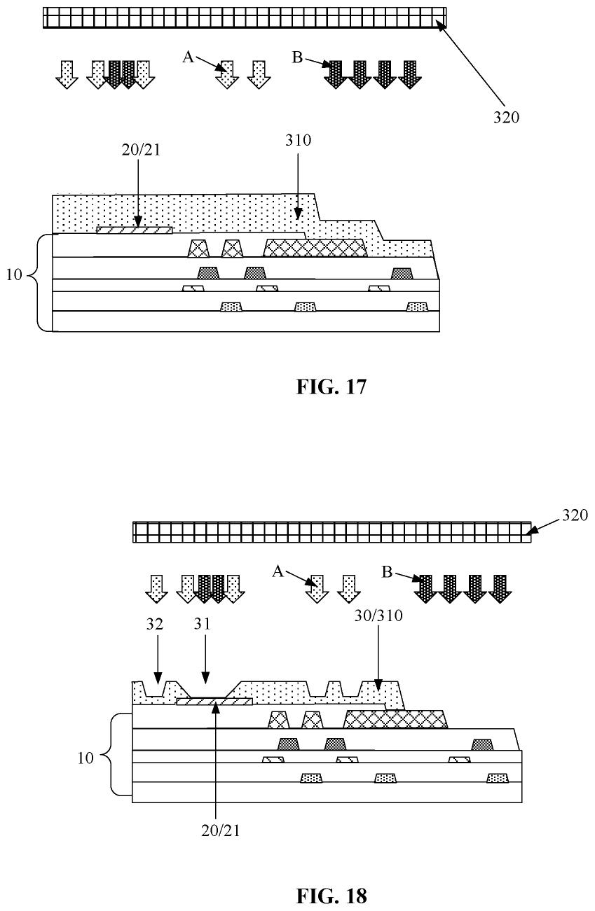

As shown in FIG. 17, a mask 320 is placed on a side of the positive photoresist layer 310 away from the first substrate 10; by using the mask 320 as a mask, a first region of the positive photoresist layer 310 is exposed with light of a first dose A, and a second region of the positive photoresist layer 310 is exposed with light of a second dose B, and the first dose A is smaller than the second dose B.

As shown in FIG. 18, development is performed on the exposed positive photoresist layer 310, to form a groove 32 in the first region and a first opening 31 in the second region. Since the first dose is smaller than the second dose, the depth of the formed groove 32 is smaller than the depth of the formed first opening 31. In this embodiment, the position of the first opening 31 corresponds to the position of the anode unit 21, the position of the groove 32 corresponds to a gap between adjacent anode units 21. The first opening 31 penetrates the positive photoresist layer 310, and the first opening 31 exposes a part of the surface of the corresponding anode unit 21, realizing electrical connection between the anode unit 21 and a subsequently formed light-emitting unit, and the groove 32 does not penetrate the positive photoresist layer 310, to increase the adhesion between the positive photoresist layer 310 and the first substrate 10, and prevent the anode unit 21 from being exposed at the position corresponding to the groove 32.

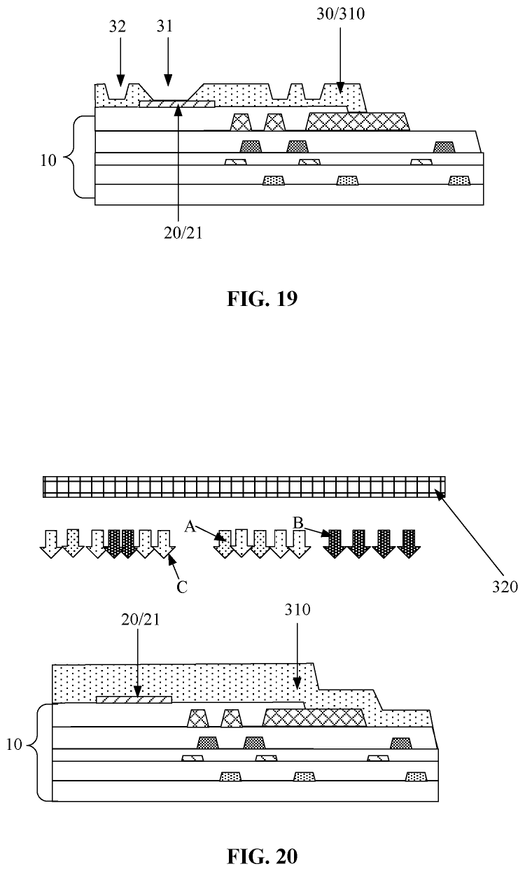

Initial curing is performed on the developed positive photoresist layer 310 at a temperature in a range of 150 °C-180 °C, to obtain the pixel definition layer 30, as shown in FIG. 19. Further, after performing initial curing on the developed positive photoresist layer 310 at a temperature in the range of 150 °C-180 °C, the method further includes: performing deep curing on the pixel definition layer 30 at a temperature in a range of 230 °C-270 °C, and the pixel definition layer 30 is completely cured.

In this embodiment, the positive photoresist layer may include a first region, a second region and a third region, and the first region is the position of the groove and is used to form the groove, the second region is the region of the first opening and is used to form the first opening, and the third region is an unexposed region of the positive photoresist layer and is used to form the part of the pixel definition layer excluding the groove and the first opening.

It should also be noted that in this embodiment, during the development of the positive photoresist layer, a thickness loss may occur, and therefore, in this embodiment, the thickness of the pixel definition layer may be equal to the thickness of the positive photoresist layer, or may be smaller than the thickness of the positive photoresist layer.

In addition, in this embodiment, the initial curing is performed at 150 °C-180 °C, which can realize low-temperature loading, and the material undergoes thermal cross-linking, Tg (glass transition temperature) increases, and no obvious reflow occurs during the subsequent high-temperature process; the deep curing is performed at 230 °C-270 °C, which can completely cure the pixel definition layer 30, to inhibit it from absorbing water or releasing small organic molecules in subsequent processes.

In addition, in this embodiment, a first inclination angle is formed between the sidewall of the first opening and the bottom of the first opening, a second inclination angle is formed between the sidewall of the groove and the bottom of the groove, and the first inclination angle is greater than the second inclination angle, and the first opening has a larger inclination angle and a relatively gentle sidewall slope, thereby ensuring continuity of each layer at the first opening when subsequently forming the layers in the first opening; meanwhile, by using a smaller inclination angle, the sidewall slope of the groove is steeper, enabling poor continuity of the subsequently formed layers at the groove, or enabling thinner thickness at the corner of the groove, further increasing the lateral resistance of each layer at the groove, reducing transmission of lateral current, lowering the probability of unintended lighting occurring during display of the display panel, and alleviating the color shift phenomenon of the display panel.

The development of a negative photoresist layer is “switch” type. In its development process: above a critical exposure dose, the photoresist layer becomes completely insoluble, and below this dose, it remains completely soluble (or nearly completely soluble). Although there is a transition zone near the critical dose, this transition zone is usually very narrow and difficult to accurately control, and the groove and the first opening cannot be formed in the same process step. In the embodiment of the present disclosure, the pixel definition layer is formed with a positive photoresist layer, then the groove and the first opening can be formed in the same process step, and the first inclination angle and the second inclination angle can be different from each other.

It should also be noted that in this embodiment, the first inclination angle and the second inclination angle are formed together with the formation of the groove and the first opening, to further simplify the process flow of the display panel. In one embodiment, the sidewall region of the groove and the sidewall region of the first opening are exposed with light of a gradient dose and then developed. In this embodiment, when the first inclination angle and the second inclination angle are formed by exposure with light at a gradient dose, the gradient dose may be a linearly gradient dose or a non-linearly gradient dose. The present disclosure is not limited in this aspect, and may vary depending on the specific circumstances. For example, in the sidewall region of the groove, the exposure dose may be gradually changed from the first dose corresponding to the groove region to the dose required for the part of the pixel definition layer excluding the groove and the first opening region (the dose may be zero or other values, depending on the specific situation) in a linear gradient or a non-linear gradient manner. The present disclosure is not limited in this aspect, and may vary depending on the specific circumstances.

In another embodiment of the present disclosure, the method further includes: forming a support on a side of the pixel definition layer away from the first substrate, to support a mask when forming subsequent layers after the light-emitting layers are formed, preventing the mask from touching the light-emitting layers and damaging the light-emitting layers, affecting the display of the display panel, and also preventing the mask from being worn.

In one embodiment of the present disclosure, the support and the pixel definition layer are formed as an integral structure, and the support and the pixel definition layer can be formed using the same layer, simplifying the process flow of the display panel and reducing the cost of the display panel. In this embodiment, forming the pixel definition layer on the side of the anode layer away from the first substrate and forming the support on the side of the pixel definition layer away from the first substrate includes the following steps.

Continuing to refer to FIG. 16, a positive photoresist layer 310 having a third thickness is formed on the side of the anode layer 20 away from the first substrate 10.

As shown in FIG. 20, a first region of the positive photoresist layer 310 is exposed with light of a first dose A, a second region of the positive photoresist layer 310 is exposed with light of a second dose B, and a third region of the positive photoresist layer 310 is exposed with light of a third dose C, and the first dose A is smaller than the second dose B, and the third dose C is smaller than the first dose A.

As shown in FIG. 20, the exposed positive photoresist layer 310 is developed to form a groove 32 in the first region, a first opening 31 in the second region, and a thickness of the pixel definition layer 30 in the third region.

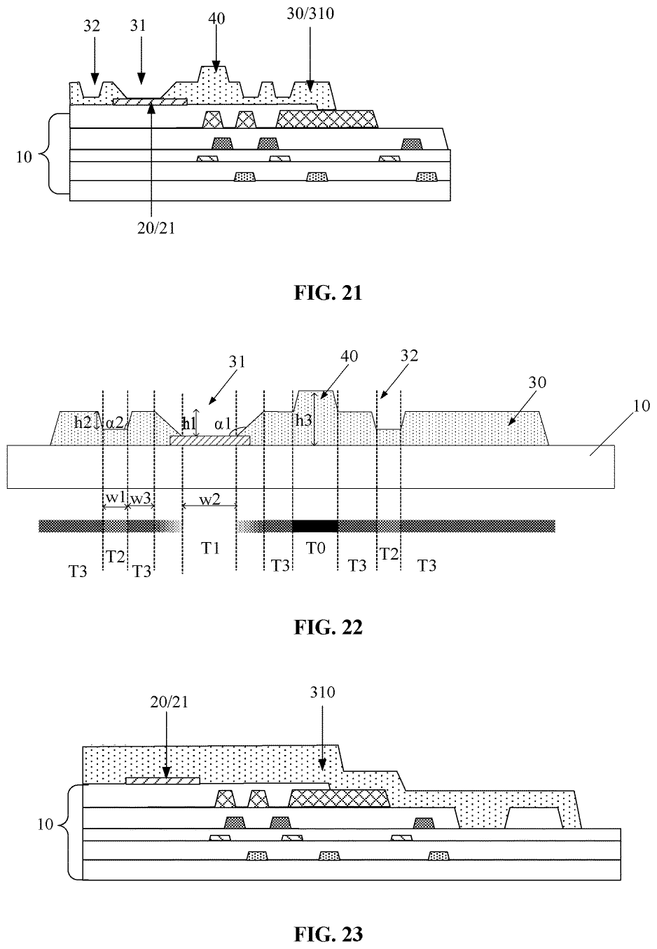

Initial curing is performed on the developed positive photoresist layer 310 at a temperature in a range of 150 °C-180 °C, to obtain the pixel definition layer 30 and a support 40 disposed on a side of the pixel definition layer 30 away from the first substrate 10, as shown in FIG. 21. Further, after performing initial curing on the developed positive photoresist layer 310 at a temperature in the range of 150 °C-180 °C, the method further includes: performing deep curing on the pixel definition layer 30 and the support 40 at a temperature in a range of 230 °C-270 °C, and the pixel definition layer 30 and the support 40 are completely cured.

In this embodiment, the positive photoresist layer includes a first region, a second region, a third region and a fifth region, and the first region corresponds to the position of the groove and is used to form the groove, the second region corresponds to the position of the first opening and is used to form the first opening, the fifth region corresponds to the position of the support and is used to form the support, and the third region corresponds to the positions of the positive photoresist layer excluding the groove, the first opening and the support, i.e., the part of the pixel definition layer excluding the groove and the first opening. In this embodiment, the exposure dose of the fifth region of the positive photoresist layer may be zero.

In one embodiment of the present disclosure, the support has a fourth thickness, the maximum thickness of the pixel definition layer is a first thickness, a portion of the pixel definition layer corresponding to the groove has a second thickness, the first opening penetrates the positive photoresist layer, the fourth thickness is smaller than or equal to the third thickness, and the fourth thickness is greater than the first thickness, and the first thickness is greater than the second thickness.

In one embodiment of the present disclosure, as shown in FIG. 22, in the positive photoresist layer, the exposure dose of the region other than the first region for forming the groove 32, the second region for forming the first opening 31, and the third region for forming the pixel definition layer 30 (i.e., the fifth region) is T0, T0 corresponds to 0% exposure, i.e., no exposure; the exposure dose of the second region for forming the first opening 31 in the positive photoresist layer is T1, T1 corresponds to 100% exposure, i.e., complete exposure; the exposure dose of the first region for forming the groove 32 in the positive photoresist layer is T2, T2 is 45%-55% of T1; the exposure dose of the third region for forming the pixel definition layer 30 in the positive photoresist layer is T3, T3 is 25%-35% of T1; and the exposure dose of the region corresponding to the sidewall of the first opening transitions from T3 to T1; in one embodiment, the support 40, the first opening 31, the groove 32 and the pixel definition layer 30 with different thicknesses can be obtained through one development process, simplifying the process flow of the display panel.

In one embodiment of the present disclosure, in the region corresponding to the sidewall of the first opening, the gradient trend of the exposure dose transitioning from T3 to T1 follows a parabolic shape. The present disclosure is not limited in this aspect, and may vary depending on the specific circumstances.

In one embodiment of the present disclosure, the thickness of the positive photoresist layer is 3 microns, the depth h2 of the groove 32 is 0.7 μm, the depth h1 of the first opening 31 is 1.1 μm, the width w1 of the bottom of the groove 32 is 2 μm, the width w2 of the bottom of the first opening 31 is 20 μm, the width w3 of the sidewall of the first opening 31 is 3 μm, the first inclination angle α1 is 150°, and the second inclination angle α2 is 110°. The present disclosure is not limited in this aspect, and may vary depending on the specific circumstances.

In yet another embodiment of the present disclosure, the display panel further includes a barrier structure, and when subsequently encapsulating structures such as the pixel definition layer and the anode layer, the barrier structure is used to limit a boundary of an organic layer in an encapsulation layer, preventing water and oxygen of the external environment from entering the interior of the display panel via the organic layer in the encapsulation layer and affecting the display of the display panel. In one embodiment of the present disclosure, the barrier structure and the pixel definition layer are formed in the same process step, to further simplify the process of the display panel and reduce the cost of the display panel.

In this embodiment, forming the pixel definition layer on the side of the anode layer away from the first substrate and forming the support on the side of the pixel definition layer away from the first substrate includes the following steps.

As shown in FIG. 23, a positive photoresist layer 310 having a third thickness is formed on the side of the anode layer 20 away from the first substrate 10.

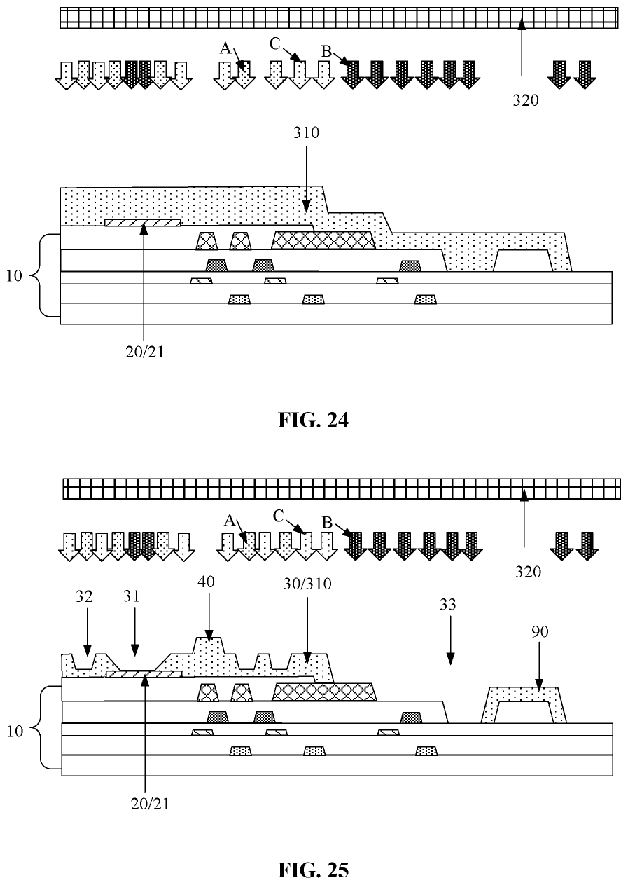

As shown in FIG. 24, a first region of the positive photoresist layer 310 is exposed with light of a first dose A, a second region and a fourth region of the positive photoresist layer 310 are exposed with light of a second dose B, and a third region of the positive photoresist layer 310 is exposed with light of a third dose C, and the first region is a region where the groove 32 is to be formed, the second region is a region where the first opening 31 and the second opening 33 are to be formed, the third region is a region where the pixel definition layer 30 is to be formed, the first dose is smaller than the second dose, and the third dose is smaller than the first dose.

As shown in FIG. 25, the exposed positive photoresist layer 310 is developed, to form a groove 32 in the first region, a first opening 31 in the second region, a pixel definition layer 30 in the third region, and a second opening 33 in the fourth region.

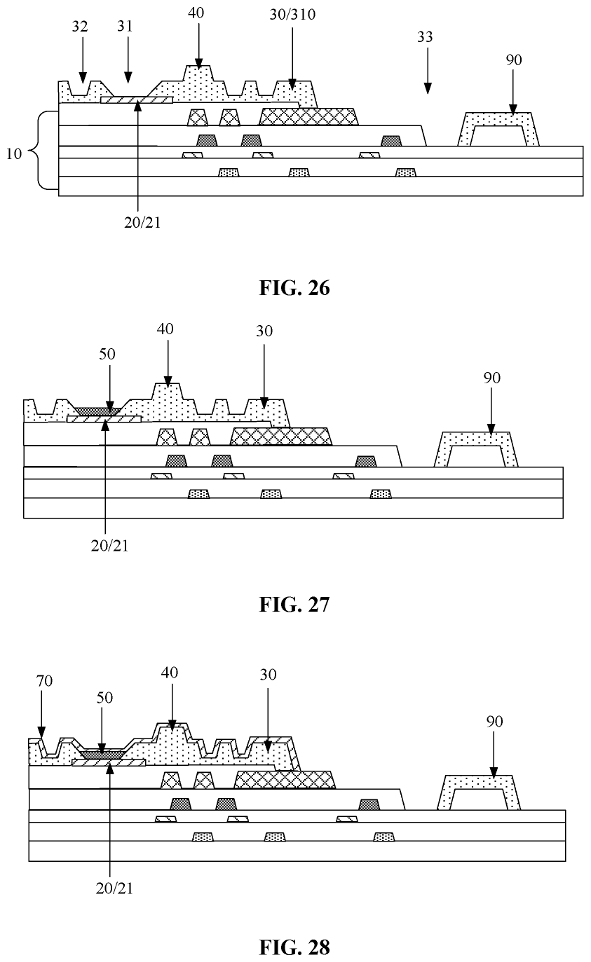

Initial curing is performed on the developed positive photoresist layer 310 at a temperature in a range of 150 °C-180 °C, to obtain the pixel definition layer 30, the support 40 and the barrier structure 90, as shown in FIG. 26. Further, after performing initial curing on the developed positive photoresist layer 310 at a temperature in the range of 150 °C-180 °C, the method further includes: performing deep curing on the pixel definition layer 30, the support 40 and the barrier structure 90 at a temperature in a range of 230 °C-270 °C, and the pixel definition layer 30, the support 40 and the barrier structure 90 are completely cured.

In this embodiment, the positive photoresist layer further includes a fifth region in addition to the first region, the second region, the third region and the fourth region, and the first region corresponds to the position of the groove and is used to form the groove, the second region corresponds to the position of the first opening and is used to form the first opening, the fourth region corresponds to the second opening and is used to form the second opening, the fifth region corresponds to the position of the support and is used to form the support, and the third region corresponds to the position of the positive photoresist layer excluding the groove, the first opening and the support, i.e., the part of the pixel definition layer excluding the groove, the first opening and the support. In this embodiment, the exposure dose of the fifth region of the positive photoresist layer may be zero.

It should also be noted that in this embodiment, the various structures formed using the positive photoresist layer, such as the groove, the first opening, the pixel definition layer and the second opening, are formed through the same development process. Therefore, in this embodiment, the groove, the first opening and the pixel definition layer have the same surface roughness, meaning they meet the same criteria, including identical roughness or identical roughness within process tolerances.

In one embodiment of the present disclosure, the support and the barrier structure each have a fourth thickness, the maximum thickness of the pixel definition layer is a first thickness, a portion of the pixel definition layer corresponding to the groove has a second thickness, the first opening and the second opening penetrate the positive photoresist layer, the fourth thickness is smaller than or equal to the third thickness, and the fourth thickness is greater than the first thickness, and the first thickness is greater than the second thickness. In this embodiment, the second opening is disposed at an edge of a display area of the display panel, and a portion of the positive photoresist layer on a side of the second opening away from the display area serves as the barrier structure.

It can be seen that the manufacturing method provided by the embodiments of the present disclosure can expose different regions of the positive photoresist layer with different doses to remove different thicknesses in different regions of the positive photoresist layer, so that the groove, the first opening, the barrier structure, the pixel definition layer, and the support are formed in the same process step, greatly simplifying the process of the display panel.

In any of the above embodiments, the transition regions among different parts in the pixel definition layer, such as the sidewall region of the groove, the sidewall region of the first opening, and the sidewall regions of the support and/or the barrier structure in the case where the display panel includes the support and/or the barrier structure, can be obtained by exposure with a gradient exposure dose and then development. In one embodiment, in the transition regions among different parts in the pixel definition layer, the exposure dose may be linearly gradient or non-linearly gradient, and the present disclosure is not limited in this aspect, and may vary depending on the specific circumstances.

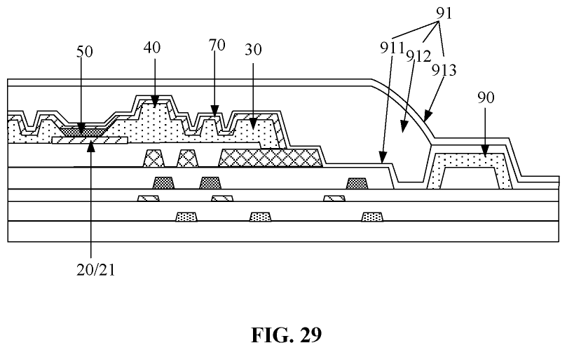

Based on any of the above embodiments, in an embodiment of the present disclosure, the manufacturing method further includes: forming a light-emitting layer 50 in the first opening, as shown in FIG. 27; forming a cathode layer 70 covering the light-emitting layer 50 and the pixel definition layer 30, as shown in FIG. 28, to control the light-emitting state of the light-emitting layer 50 using the cathode layer 70 and the anode units 21; forming an encapsulation layer to encapsulate various structures formed on the first substrate, as shown in FIG. 29. In one embodiment, the encapsulation layer 91 includes a stacked first inorganic layer 911, an organic layer 912 and a second inorganic layer 913, to improve the effect of the encapsulation layer 91 in isolating water and oxygen from the external environment. However, the present disclosure is not limited in this aspect, and may vary depending on the specific circumstances.

In summary, in the display panel, the manufacturing method thereof, and the display device provided by the embodiments of the present disclosure, the pixel definition layer 30 not only includes the first openings 31 for at least partially exposing the surface of the respective anode units 21, and subsequently formed light-emitting units are electrically connected to the anode units 21 through the first openings 31, but also includes the grooves 32, the projections of the grooves 32 on the first substrate 10 being within the gaps between projections of adjacent anode units 21 on the first substrate 10. Thus, by providing the grooves 32 between adjacent anode units 21 in a plane parallel to the first substrate 10, the lateral resistance of each continuous layer structure formed on the pixel definition layer 30 away from the first substrate 10 is increased, transmission of lateral current is reduced, the probability of unintended lighting occurring during display of the display panel is reduced, and the color shift phenomenon of the display panel is improved.

Moreover, in the display panel, the manufacturing method thereof, and the display device provided by the embodiments of the present disclosure, the grooves 32 do not penetrate the pixel definition layer 30, and only extend into a partial depth inside the pixel definition layer 30, to increase the contact area between the first substrate 10 and the pixel definition layer 30 and improve the adhesion between the first substrate 10 and the pixel definition layer 30, and also prevent the anode units 21 from being exposed at the position corresponding to the grooves 32.

In addition, in the display panel, the manufacturing method thereof, and the display device provided by the embodiments of the present disclosure, a first inclination angle α1 is formed between the sidewall of the first opening 31 and the bottom of the first opening 31, a second inclination angle α2 is formed between the sidewall of the groove 32 and the bottom of the groove 32, and the first inclination angle α1 is greater than the second inclination angle α2, and the first opening 31 has a larger inclination angle and a relatively gentle sidewall slope, thereby ensuring continuity of each layer at the first opening 31 when subsequently forming the layers in the first opening 31; meanwhile, by using a smaller inclination angle, the sidewall slope of the groove 32 is steeper, enabling poor continuity of the subsequently formed layers at the groove 32, or enabling thinner thickness at the corner of the groove 32, further increasing the lateral resistance of each layer at the groove 32, reducing transmission of lateral current, lowering the probability of unintended lighting occurring during display of the display panel, and alleviating the color shift phenomenon of the display panel.

The above description is only preferred embodiments of the present disclosure. Although the present disclosure has been disclosed as above with preferred embodiments, it is not intended to limit the present disclosure. Without departing from the scope of the embodiments of the present application, any person may, by utilizing the methods and technical content disclosed above, make numerous variations and modifications to the embodiments of the present application, or modify them into equivalent embodiments with equivalent changes. Therefore, any simple modifications, equivalent changes and modifications made to the above embodiments according to the technical essence of the present disclosure without departing from the present disclosure still fall within the scope of the present disclosure.

What is claimed is:

1. A display panel, comprising:
a first substrate;
an anode layer disposed on a first side of the first substrate, the anode layer comprising a plurality of anode units; and
a pixel definition layer disposed on a side of the anode layer away from the first substrate, the pixel definition layer having a plurality of first openings and a plurality of grooves, wherein the first openings correspond to the respective anode units, penetrate the pixel definition layer, and expose at least a portion of a surface of the respective anode units, and a projection of each groove on the first substrate is within a gap between projections of adjacent anode units on the first substrate;
wherein, for each of the plurality of first openings and each of the plurality of grooves, a first inclination angle is formed between a sidewall of the first opening and a bottom of the first opening, a second inclination angle is formed between a sidewall of the groove and a bottom of the groove, and the first inclination angle is greater than the second inclination angle.

2. The display panel according to claim 1, wherein the first inclination angle ranges from 140° to 160°, and the second inclination angle ranges from 90° to 120°.

3. The display panel according to claim 1, further comprising:
a support disposed on a side of the pixel definition layer away from the first substrate, wherein a projection of the support on the first substrate is within the gap between the projections of the adjacent anode units on the first substrate.

4. The display panel according to claim 3, wherein the support and the pixel definition layer are formed as an integral structure.

5. The display panel according to claim 1, wherein the pixel definition layer is a positive photoresist layer, and the grooves and the first openings are formed in a same process step.

6. The display panel according to claim 5, wherein a formation process of the grooves and the first openings comprises exposure, development and curing, wherein an exposure dose corresponding to a region of the grooves is smaller than an exposure dose corresponding to a region of the first openings, and the curing comprises initial curing performed at a temperature range of 150 °C-180 °C.

7. The display panel according to claim 1, wherein the pixel definition layer is a light-absorbing layer.

8. The display panel according to claim 1, further comprising:
at least two light-emitting layers disposed on a side of the anode layer away from the first substrate, the light-emitting layers comprising periodically arranged light-emitting units of a first color, light-emitting units of a second color, and light-emitting units of a third color;
a charge generation layer disposed between the light-emitting layers that are adjacent to each other; and
a cathode layer disposed on a side of the at least two light-emitting layers away from the first substrate.

9. The display panel according to claim 8, wherein the groove surrounds the first opening, and a projection of the groove on the first substrate is a non-closed loop.

10. The display panel according to claim 9, wherein the display panel comprises light-emitting units of at least two colors, and portions of the cathode layer corresponding to light-emitting units of different colors are formed as an integral structure.

11. The display panel according to claim 1, further comprising:
a barrier structure disposed on the first side of the first substrate and around a display area of the display panel, wherein the barrier structure and the pixel definition layer are formed in a same process step.

12. A display device, comprising the display panel according to claim 1.

13. A manufacturing method of a display panel, comprising:
forming a first substrate;
forming an anode layer on a first side of the first substrate, the anode layer comprising a plurality of anode units; and
forming a pixel definition layer on a side of the anode layer away from the first substrate, the pixel definition layer having a plurality of first openings and a plurality of grooves, wherein the first openings correspond to the respective anode units, penetrate the pixel definition layer, and expose at least a portion of a surface of the respective anode units, and a projection of each groove on the first substrate is within a gap between projections of adjacent anode units on the first substrate;
wherein, for each of the plurality of first openings and each of the plurality of grooves, a first inclination angle is formed between a sidewall of the first opening and a bottom of the first opening, a second inclination angle is formed between a sidewall of the groove and a bottom of the groove, and the first inclination angle is greater than the second inclination angle.

14. The manufacturing method according to claim 13, wherein forming the pixel definition layer on the side of the anode layer away from the first substrate comprises:
forming a positive photoresist layer on the side of the anode layer away from the first substrate;
exposing a first region of the positive photoresist layer with light of a first dose, and exposing a second region of the positive photoresist layer with light of a second dose, wherein the first dose is smaller than the second dose;
developing the exposed positive photoresist layer, to form the grooves in the first region and the first openings in the second region, a depth of the grooves being smaller than a depth of the first openings, and the first openings penetrating the positive photoresist layer; and
performing initial curing on the developed positive photoresist layer at a temperature range of 150 °C-180 °C, to obtain the pixel definition layer.

15. The manufacturing method according to claim 13, further comprising:
forming a support on a side of the pixel definition layer away from the first substrate, wherein a projection of the support on the first substrate is within the gap between the projections of the adjacent anode units on the first substrate.

16. The manufacturing method according to claim 15, wherein the support and the pixel definition layer are formed as an integral structure, and forming the pixel definition layer on the side of the anode layer away from the first substrate and forming the support on the side of the pixel definition layer away from the first substrate comprises:
forming a positive photoresist layer having a third thickness on the side of the anode layer away from the first substrate;
exposing a first region of the positive photoresist layer with light of a first dose, exposing a second region of the positive photoresist layer with light of a second dose, and exposing a third region of the positive photoresist layer with light of a third dose, wherein the first dose is smaller than the second dose, and the third dose is smaller than the first dose;
developing the exposed positive photoresist layer, to form the grooves in the first region, the first openings in the second region, and a thickness of the pixel definition layer in the third region; and
performing initial curing on the developed positive photoresist layer at a temperature range of 150 °C-180 °C, to obtain the pixel definition layer and the support disposed on the side of the pixel definition layer away from the first substrate;
wherein the support has a fourth thickness, a maximum thickness of the pixel definition layer is a first thickness, a portion of the pixel definition layer corresponding to the grooves has a second thickness, the first openings penetrate the positive photoresist layer, the fourth thickness is smaller than or equal to the third thickness, the fourth thickness is greater than the first thickness, and the first thickness is greater than the second thickness.

17. The manufacturing method according to claim 16, wherein an exposure dose of the positive photoresist layer in regions other than the first region, the second region and the third region is zero, an exposure dose of the second region of the positive photoresist layer is a full exposure, an exposure dose of the first region of the positive photoresist layer is 45%-55% of the exposure dose of the second region, and an exposure dose of the third region of the positive photoresist layer is 25%-35% of the exposure dose of the second region.

18. The manufacturing method according to claim 15, wherein the display panel further comprises a barrier structure, and forming the pixel definition layer on the side of the anode layer away from the first substrate and forming the support on the side of the pixel definition layer away from the first substrate comprises:
forming a positive photoresist layer having a third thickness on the side of the anode layer away from the first substrate;
exposing a first region of the positive photoresist layer with light of a first dose, exposing a second region and a fourth region of the positive photoresist layer with light of a second dose, and exposing a third region of the positive photoresist layer with light of a third dose, wherein the first region is a region where the grooves are to be formed, the second region is a region where the first openings are to be formed, the fourth region is a region where second openings are to be formed, the third region is a region where the pixel definition layer is to be formed, the first dose is smaller than the second dose, and the third dose is smaller than the first dose;
developing the exposed positive photoresist layer, to form the grooves in the first region, the first openings in the second region, the pixel definition layer in the third region, and the second openings in the fourth region; and
performing initial curing on the developed positive photoresist layer at a temperature range of 150 °C-180 °C, to obtain the pixel definition layer, the support and the barrier structure;
wherein the support and the barrier structure each have a fourth thickness, a maximum thickness of the pixel definition layer is a first thickness, a portion of the pixel definition layer corresponding to the grooves has a second thickness, the first openings and the second openings penetrate the positive photoresist layer, the fourth thickness is smaller than or equal to the third thickness, the fourth thickness is greater than the first thickness, and the first thickness is greater than the second thickness, the second openings are disposed at an edge of a display area of the display panel, and a portion of the positive photoresist layer on a side of the second openings away from the display area is the barrier structure.
